(19) United States
(12) Patent Application Publication
(10) Pub. No.: US 2015/0168241 A1
(43) Pub. Date: Jun. 18, 2015

(54) STRAIN GAUGE ARRANGEMENT

(71) Applicant: Schaeffler Technologies GmbH & Co. KG, Herzogenaurach (DE)

(72) Inventors: Jürgen Gierl, Erlangen (DE); Jens Heim, Bergrheinfeld (DE); Jakob Schillinger, Gaimersheim (DE)

(73) Assignee: Schaeffler Technologies GmbH & Co. KG, Herzogenaurach (DE)

(21) Appl. No.: 14/403,236

(22) PCT Filed: May 16, 2013
(86) PCT No.: PCT/EP2013/060114

§ 371 Date: Nov. 24, 2014

(30) Foreign Application Priority Data
May 22, 2012 (DE) 10 2012 208 492.4

(51) Int. Cl. G01L 5/00; C23C 16/50; C23C 16/56; C23C 14/58

(52) U.S. Cl. CPC G01L 5/0019; C23C 14/5873; C23C 16/50; C23C 16/56

(57) ABSTRACT

A method is specified for producing a strain gauge arrangement (14) on a surface of a machine element (2), particularly a bearing ring (3) or a shaft (17), wherein a deformation-sensitive measurement layer (6) and a protective layer (8) situated thereabove are applied to the surface. The protective layer (8) is locally removed by laser processing and the exposed measurement layer (6) is contacted electrically. A machine element (2), particularly a bearing ring (3) or a shaft (17), with a strain gauge arrangement (14) produced according to the method is also provided.

### FIELD OF THE INVENTION

The invention relates to a method for producing a strain gauge arrangement on the surface of a machine element, as well as to a machine element with a strain gauge arrangement that has been produced according to such a method.

### BACKGROUND

To determine the stress in a machine element, normally the deformation of the component is measured. A strain gauge arrangement that detects the deformation on the surface of the machine element is typically used here.

The strain gauge arrangement can usually detect a positive elongation (stretching), as well as a negative elongation (compaction). To do this, the strain gauge arrangement is typically mounted using a material-locking fit to a point of the machine element surface to be measured. If the machine element is then deformed at this point, the strain gauge arrangement also deforms accordingly. This deformation changes a parameter of the strain gauge arrangement, for example, the electrical resistance. This parameter is detected for measurement. The strain gauge arrangement typically consists of a metallic or ceramic material or a semiconductor material.

In a typical strain gauge arrangement, a metal film is deposited on a plastic substrate and provided with electrical terminals. So that a sufficiently high resistance is achieved, the conductive track is etched into a meander-like shape. A second plastic film is bonded tightly to the plastic substrate on the top side, in order to protect the resistive material from adverse external effects.

A strain gauge arrangement can typically also be deposited using thin-film technology, for example, through vapor deposition or sputtering, directly onto the machine element surface to be measured. Here, in particular, a measurement layer is deposited over the entire surface and structured accordingly through laser material processing or by a photolithographic method. A protective layer that protects the measurement layer against external effects is typically also deposited on this measurement layer over the entire surface.

It is problematic here, however, that the protective layer deposited over the entire surface also covers contact points of the measurement layer with this protective layer. The whole-area coating prevents the contacting of the contact points of the measurement layer with a corresponding evaluation unit for detecting and evaluating the changes in the parameter, for example, the change in resistance, and is typically partially removed with expensive mask processes and etching equipment using a photolithographic procedure.

### SUMMARY

A first objective of the invention is to provide a method for producing a strain gauge arrangement on the surface of a machine element, in particular, a bearing ring or a shaft, which can be produced simply and economically.

A second objective is to provide a machine element, in particular, a bearing ring or a shaft, with a strain gauge arrangement, which is simple and economical to produce.

The first objective is met by a method according to the invention. Advantageous embodiments and refinements of the invention are described in the claims and the following description.

In the method according to the invention for producing a strain gauge arrangement on the surface of a machine element, in particular, of a bearing ring or a shaft, a measurement layer that is sensitive to deformation and a protective layer above this measurement layer are deposited on the surface. The protective layer is locally removed by means of a laser processing and the exposed sensor layer is contacted electrically.

The invention starts from the idea of designing a production method to realize the most economical production possible. This is applicable even more for series production in which a simplification of an individual production step already results in large time and costs savings overall. The invention further starts from the idea that it is more economical for the production of a strain gauge arrangement on the surface of a machine element, especially on uneven surfaces, to first deposit the protective layer over the entire area of the measurement layer and only after this to locally remove the protective layer in a targeted way. Therefore, the invention provides first the deposition of the protective layer over the entire area and to locally remove the protective layer only in a subsequent production step by a precise and simple laser processing step at the required areas. In this way, the invention allows an automated and economical production sequence.

The machine element can be, in particular, the shaft or the bearing ring of an anti-friction bearing. This can have, for example, a standard configuration, such as a ball joint bearing, an angular contact ball bearing, a cylindrical roller bearing, or a tapered roller bearing, as well as a special configuration, such as a wheel bearing. The bearing ring can be both an outer ring with a one-part design or split design and also an inner ring with a one-part design or split design in a corresponding anti-friction bearing. The shaft can be both a hollow shaft and also a solid shaft.

The strain gauge arrangement can basically be mounted at any position of the machine element surface. For a bearing ring, the strain gauge arrangement could be mounted at a point of the radially outer lateral surface, as well as at an end face surface area. The same applies accordingly for the mounting on a shaft. Here, only one strain gauge arrangement could be mounted at a corresponding point of the machine element. However, it is also possible to mount several strain gauge arrangements on the surface of the machine element, wherein these can be mounted, in particular, at different points of the surface.

The measurement layer that is sensitive to deformation is formed, in particular, from a metallic material or a semiconductor material. In particular, the measurement layer could be made from a nickel alloy or from titanium oxynitride. The measurement layer has at least one contact point that is used for the electrical contacting of the measurement layer, for example, with a corresponding evaluation unit for detecting and evaluating the change in resistance.

During operation, the measurement layer deforms in accordance with a deformation of the machine element, that is, a deformation of the machine element is “transferred” to the measurement layer. The measurement layer here experiences, depending on the deformation, positive elongation (stretching) or negative elongation (compaction). The deformation of the measurement layer changes its electrical resistance compared with the non-deformed measurement layer. This relative change in resistance can be traced back, in particular, to two causes: First to the change in the geometry of the measurement layer: elongation changes the length and cross-sectional area of the measurement layer. This is especially pronounced in a measurement layer made from a metallic material and is responsible here for the relative change in resistance. Second, the relative change in resistance can be traced back to the piezoelectric effect. This effect is very pronounced especially for a measurement layer made from a semiconductor material, while here the influence of the change in geometry can be essentially ignored. Here, the deformation of the crystal lattice and thus of the band structure changes the number of electrons in the conduction band and thus the conductivity of the material. Due to the very strongly pronounced piezo-resistive effect in semiconductors, the sensitivity of semiconductors to elongation is overall greater than that of metals.

The protective layer is used essentially for protecting the measurement layer from contaminants, corrosion, and mechanical damage, as well as from undesired contact of the measurement layer with conductive materials.

For the mounting of the strain gauge arrangement on the surface of a machine element, initially the measurement layer and above this the protective layer are deposited, each with a thickness, in particular, in the nanometer to micrometer range. In another production step, the protective layer is removed locally by a laser processing step. Here, the protective layer is removed, in particular, in the area of at least one contact point. The removal by laser processing is performed, for example, by means of laser ablation. The laser radiation that is used here leads to heating and evaporation of the material. The measurement layer under the protective layer to be removed is not negatively affected by the laser processing. The measurement layer is then electrically contacted via the at least one contact point that has been exposed in this way.

The described method has the advantage of a simple and economical production method for a strain gauge arrangement on the surface of a machine element. The local removal of the protective layer performed at a later time makes it possible to deposit the protective layer first over the entire area of the measurement layer. For the deposition of the protective layer, no special and partially very expensive and cost-intensive methods or devices must be provided that allow only a partial deposition of a protective coating on the measurement layer. The whole-area protective coating also reduces the likelihood that the at least one contact point becomes contaminated before the electrical contacting, because the contact point is exposed just before the contacting. The local removal of the protective layer by means of laser processing also allows a simple and exact opening of the at least one contact point, without here negatively affecting the measurement layer or the surrounding protective layer. Furthermore, such laser processing can be integrated in an automated production sequence.

In a preferred execution of the method, an insulation layer is deposited between the surface of the machine element and the measurement layer. Preferably here, the insulation layer, in particular, with a thickness in the nanometer or micrometer range, is first deposited on the surface of the machine element and then the measurement layer and protective layer above the insulation layer. The insulation layer is used, in particular, for the electrical insulation of the measurement layer with regard to a conductive surface of the machine element. In addition, it can also be used for protecting the measurement layer. The insulation layer is formed, for example, from aluminum oxide, silicon oxide, silicon nitride, or a combination of these materials.

The measurement layer is preferably structured before the deposition of the protective layer. Here, the type of structuring is adapted especially to each requirement and is dependent, for example, on the material of the measurement layer, the expected type and magnitude of the deformation of the machine element, and the area of the point to be measured on the surface of the machine element. In particular, the measurement layer has a meander-shaped structure. In this way, a sufficiently high resistance and thus a high sensitivity can be achieved with the smallest possible space requirements.

The structuring of the measurement layer is generated, for example, by a photolithographic method. Here, the pattern of a photo mask is transferred onto a light-sensitive photo coating, in particular, by means of exposure to light. Then the exposed points of the photo coating are dissolved (alternatively the dissolution of the non-exposed points is also possible if the photo coating is cured by the light). In this way, a lithographic mask is produced according to the desired structure that allows further processing by chemical and physical methods, for example, the deposition of the measurement layer in the open windows or the partial etching of the measurement layer below the open windows. Preferably, however, the structuring is generated by a laser process. In this way, the structure is built after the full-area deposition of the measurement layer, in particular, by laser ablation. After the structuring of the measurement layer, the protective layer is deposited over the full area of this measurement layer.

Alternatively, the structuring of the measurement layer and the removal of the protective layer is performed in one work cycle. Here, in particular, by means of laser processing with two laser settings, both the structure of the measurement layer is generated and also the at least one contact point of the measurement layer is exposed by the protective layer. In this way, the production process is further optimized with regard to time. A laser beam with a first laser setting is here used to structure the measurement layer, wherein it removes both the protective layer and also the measurement layer. A laser beam with a second laser setting is used only for the local removal of the protective layer. Here, the laser beams can be generated by a laser and one after the other with respect to time. It is also possible, however, that the laser beams are generated (partially) at the same time via several lasers.

In one advantageous execution of the method, the protective layer is deposited by a gas phase deposition, preferably by a PVD or PACVD deposition. In principle, both a physical vapor deposition (abbreviated: PVD) and also a chemical vapor deposition (abbreviated: CVD) could be used. In particular, for a PVD method, a suitable substance could be transformed into the gaseous state under the presence of feeding of a corresponding reactive gas. On the machine element, essentially a chemical compound of the elements originating from the introduced substance and from the reactive gas precipitates. In particular, in a CVD method, a gas mixture that contains corresponding reactants, flows around the measurement layer of the machine element to be coated. The molecules are dissociated by the supply of energy and the radicals are fed to a reaction, wherein a solid component that forms the protective layer is deposited. Preferably the chemical reaction is here activated by a plasma (plasma-enhanced chemical vapor deposition, abbreviated: PECVD; or also plasma-assisted chemical vapor deposition, abbreviated: PACVD).

As the protective layer, preferably a layer made from hydrogen-containing, amorphous carbon, silicon oxide, silicon nitride, and/or aluminum oxide is deposited. The protective layer can comprise, accordingly, both only hydrogen-containing, amorphous carbon, silicon oxide, silicon nitride, or aluminum oxide, and also a combination of these materials. Amorphous carbon is also known by the designation DLC (diamond-like carbon). Here, at least one layer is deposited as a hydrogen-containing, amorphous carbon layer (nomenclature: C:H) or as a modified hydrogen-containing, amorphous carbon layer (nomenclature: a-C:H:X). For a modified, hydrogen-containing, amorphous carbon layer, one or more impurity elements (X), for example, Si, O, N, or B, are also introduced. A protective layer made from one of these materials or from a combination of these is distinguished, in particular, by a high electrical resistance, in particular, greater than 200 Mohm per lam, a high hardness, and durability. In particular, the protective layer is here deposited in one or more layers.

Advantageously, the protective layer is generated with a thickness of less than 20 μm. A protective layer with such a thickness offers sufficient protection of the measurement layer from mechanical damage.

The exposed measurement layer is advantageously cleaned before the contacting, in order to remove any possible oxides or other contaminants. This cleaning can be performed, in particular, by means of plasma cleaning or dry ice blasting.

After the contacting, the measurement layer and the protective layer are advantageously sealed. Here, an organic or inorganic material can be used for the sealing. In this way, parts of the measurement layer that are, under some circumstances, still exposed, that is, no longer covered with a protective layer, after the laser processing and contacting, can be coated with a protective layer. Here, the protective layer is also sealed. The sealing is also used, in particular, for optional structuring of the measurement layer performed in one work cycle and removal of the protective layer, and to seal the measurement layer exposed at the sides by the structuring and partially exposed insulation layer.

The second objective of the invention is met according to further features of the invention.

The machine element according to the invention, in particular, a bearing ring or a shaft, comprises a strain gauge arrangement accordingly, which has been produced according to the previously described method.

The machine element is, in particular, a shaft or a bearing ring of an anti-friction bearing. Here, a standard configuration, for example, a ball joint bearing, an angular contact ball bearing, cylindrical roller bearing, or tapered roller bearing, as well as a special configuration, could be used. The bearing ring could be both an outer ring with a one-part design or split design and also an inner ring with a one-part design or split design in a corresponding anti-friction bearing. The shaft can be both a hollow shaft and also a solid shaft.

The strain gauge arrangement can basically be mounted at any point of the machine element surface. For a bearing ring, the strain gauge arrangement could be mounted at a point of the radially outer lateral surface, and also an end face surface area. The same applies accordingly for a shaft. Here, only one strain gauge arrangement could be mounted at a corresponding point of the machine element. It is also possible, however, that several strain gauge arrangements are mounted on the surface of the machine element, wherein these can be mounted, in particular, at different points of the surface.

The specified machine element has the advantage of a simple and economical production. Through the production of the strain gauge arrangement on the surface of the machine element according to a method of the previously described type, the machine element could be produced in a simple and economical way.

### BRIEF DESCRIPTION OF THE DRAWINGS

Embodiments of the invention are explained in more detail below with reference to the drawings. Shown therein are:

FIG. 1 after a first production step, in a schematic section view, a machine element with an insulation layer, a structured measurement layer, and a protective layer,

FIG. 2 in a second production step, in a schematic section view, laser processing for local removal of a protective layer,

FIG. 3 after a second production step, in a schematic section view, a machine element with locally exposed measurement layer,

FIG. 4 after another production step, in a schematic section view, a machine element with a strain gauge arrangement,

FIG. 5 after an alternative first production step, in a schematic section view, a machine element with an insulation layer, an unstructured measurement layer, and a protective layer,

FIG. 6 in an alternative second production step, in a schematic section view, laser processing for local removal of a protective layer and for structuring a measurement layer, and

FIG. 7 after another alternative production step, in a schematic section view, a machine element with a strain gauge arrangement.

Parts that correspond to each other are provided with identical reference symbols in all of the figures.

### DETAILED DESCRIPTION OF THE PREFERRED EMBODIMENTS

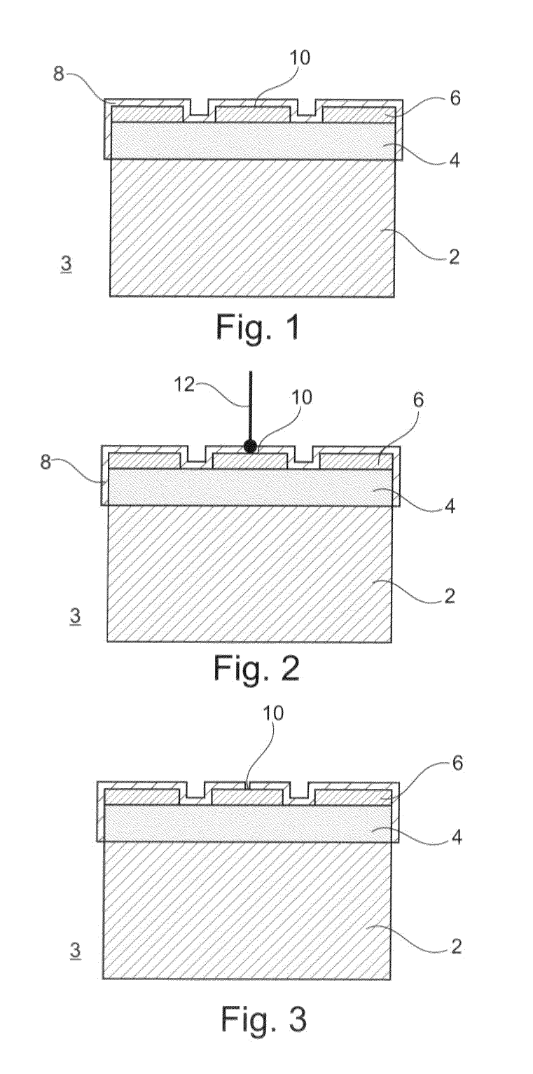

FIG. 1 illustrates a machine element 2 made from steel that is a part of a bearing ring 3 on whose surface, in a first production step, an insulation layer 4, a structured measurement layer 6, and a protective layer 8 have been deposited. The machine element 2 shown is a part of a bearing ring 9. Here, initially the insulation layer 4 is deposited on the surface of the machine element 2. The insulation layer is formed of aluminum oxide and is used, in particular, for the electrical insulation of the measurement layer 6. Alternatively, the insulation layer 4 could also be made from silicon oxide, silicon nitride, or a combination of the mentioned materials. On the insulation layer 4, a structured measurement layer 6 made from a nickel alloy or titanium oxynitride has been deposited that is used for detecting a deformation of the machine element through its own separate, corresponding deformation and thus associated change in electrical resistance during operation. The measurement layer 6 has a contact point 10 that is used for the electrical contacting of the measurement layer 6 with an evaluation unit. A protective layer 8 has been deposited over the entire surface of the measurement layer 6 via a PACVD method (plasma-assisted chemical vapor deposition). Alternatively, the protective layer 8 could also have been deposited over the full area via a PVD method (physical vapor deposition). The protective layer 8 comprises hydrogen-containing, amorphous carbon and covers the measurement layer 6 on the sides and from above, as well as the insulation layer 4 from the sides. Alternatively, the protective layer 8 could also comprise silicon oxide, silicon nitride, or a combination of these materials. The protective layer 8 has a high electrical resistance that is greater than 200 Mohm per μm, high hardness and durability, as well as a low coefficient of friction and is used essentially for protection from contaminants, corrosion, and mechanical damage, as well as from undesired contact of the measurement layer 6 with conductive materials.

FIG. 2 shows, in a second production step, laser processing for local removal of the protective layer 8. Here, the protective layer 8 is removed in the area of the contact point 10 by laser ablation. The protective layer 8 is etched with laser radiation 12. The laser radiation 12 used here leads to heating and evaporation of the material. This local removal of the protective layer 8 performed at a later time makes it possible to deposit the protective layer 8 in the previous production step initially over the entire surface of the measurement layer 6. This arrangement does not require special and sometimes very expensive methods or tools that permit only a partial deposition of a protective coating on the measurement layer 6. The local removal of the protective layer 8 by means of laser processing also allows a simple and exact exposure of the contact point 10, without negatively affecting the measurement layer 6 or the surrounding protective layer 8.

In FIG. 3, after a second production step, a machine element 2 with locally exposed measurement layer 6 is shown. Here, the measurement layer 6 has no protective layer 8 in the area of a contact point 10.

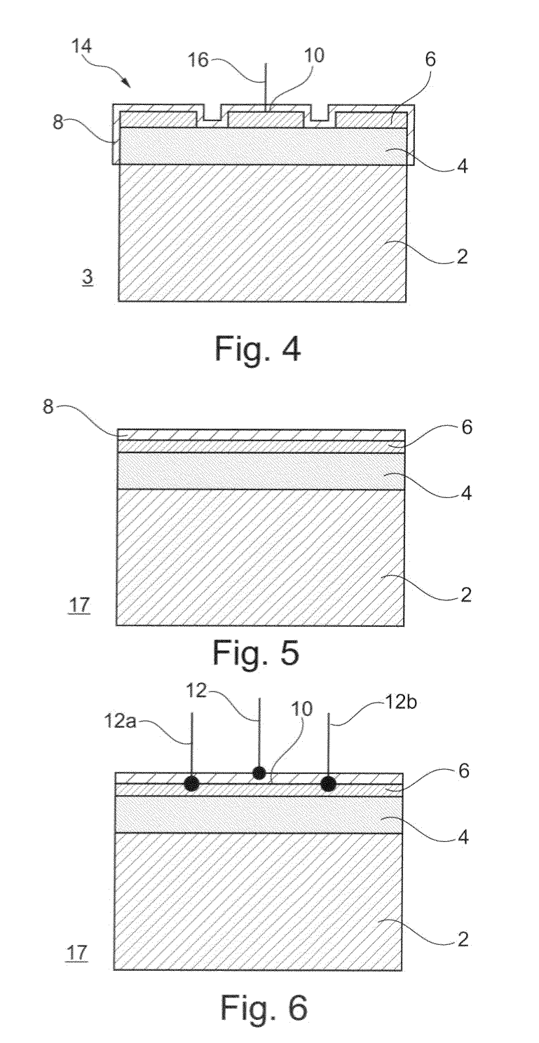

FIG. 4 shows, after another production step in which the measurement layer 6 has been electrically contacted, a machine element 2 with a strain gauge arrangement 14. The strain gauge arrangement 14 comprises an insulation layer 4, a structured measurement layer 6, and a protective layer 8. An electrical line 16 is formed on a contact point 10 of the measurement layer 6. For a deformation of the machine element 2, the strain gauge arrangement 14 and especially the measurement layer 6 are similarly deformed. This deformation changes the electrical resistance of the measurement layer 6. To detect and evaluate the change in resistance of the measurement layer 6, this can be connected by means of the electrical line 16, for example, to a corresponding evaluation unit (not shown).

FIG. 5 illustrates a machine element 2 made from steel that shows a part of a shaft 17 on whose surface, in an alternative first production step, an insulation layer 4, an unstructured measurement layer 6, and a protective layer 8 have been deposited. The measurement layer 6 is here unstructured, that is, over the whole surface between the insulation layer 4 and protective layer 8. The protective layer 8 covers the measurement layer 6 only from above. Otherwise, this machine element 2 corresponds essentially to the machine element 2 shown in FIG. 1.

In an alternative second production step, FIG. 6 shows laser processing for local removal of a protective layer 8 and for structuring a measurement layer 6. Here, the laser processing with two laser settings both generates the structure of the measurement layer 6 and also exposes a contact point 10 of the measurement layer 6 from the protective layer 8. In this way, the production process is further optimized with respect to time. The illustrated laser beams 12a, 12b with a first laser setting are here used for structuring the measurement layer 6, wherein they remove both the protective layer 8 and also the measurement layer 6. The laser beam 12 with a second laser setting is used only for the removal of the protective layer 8 in the area of the contact point 10. Here, the laser beams 12, 12a, 12b can be generated by a laser one after the other with respect to time. It is also possible, however, that the laser beams 12, 12a, 12b are generated at the same time by several lasers.

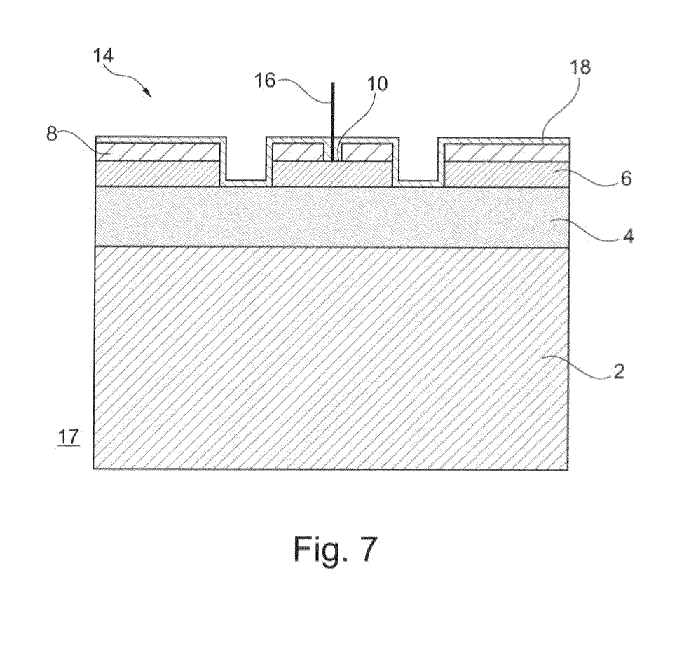

FIG. 7 shows, after another alternative production step in which the measurement layer 6 is electrically contacted and has been sealed, a machine element 2 with a strain gauge arrangement 14. The strain gauge arrangement 14 comprises an insulation layer 4, a structured measurement layer 6, and a protective layer 8. An electrical line 16 is formed on a contact point 10 of the measurement layer 6. After forming the electrical line 16, the measurement layer 6 is provided with a sealing layer 18. In this way, the measurement layer 6 that is still partially exposed, that is, no longer covered with a protective layer 8 after the laser processing and contacting, is coated with a protective sealing layer 18. Here, the still present protective layer 8 and the partially exposed insulation layer 4 due to the structuring are also sealed.

### LIST OF REFERENCE NUMBERS

2 Machine element
3 Bearing ring
4 Insulation layer
6 Measurement layer
8 Protective layer
10 Contact point
12, 12a, 12b Laser beam
14 Strain gauge arrangement
16 Electrical line
17 Shaft
18 Sealing layer

1. Method for producing a strain gauge arrangement on a surface of a machine element, comprising depositing a deformation-sensitive measurement layer and a protective layer above said measurement layer on the surface, and removing the protective layer locally via laser processing, and wherein the exposed measurement layer is contacted electrically.

2. Method according to claim 1, further comprising depositing an insulation layer between the surface of the machine element and the measurement layer.

3. Method according to claim 1, further comprising structuring the measurement layer before depositing the protective layer.

4. Method according to claim 1, further comprising structuring the measurement layer wherein the structuring and the removal of the protective layer are performed in one work cycle.

5. Method according to claim 1, wherein the protective layer is deposited by a PVD or PACVD deposition method.

6. Method according to claim 1, wherein a layer made from at least one of a hydrogen-containing, amorphous carbon, silicon oxide, silicon nitride, or aluminum oxide is deposited as the protective layer.

7. Method according to claim 1, wherein the protective layer (8) is produced with a thickness of less than 20 μm.

8. Method according to claim 1, further comprising cleaning the exposed measurement layer before the contacting.

9. Method according to claim 1, further comprising sealing the measurement layer and the protective layer after the contacts are formed.

10. A machine element with the strain gauge arrangement, produced according to claim 1.

11. Method according to claim 1, wherein the machine element is a bearing ring or a shaft.
